(19) United States
(12) Patent Application Publication
(10) Pub. No.: US 2020/0395234 A1
(43) Pub. Date: Dec. 17, 2020

(54) MULTI-COMPONENT TRAYS FOR TRANSPORTING INTEGRATED CIRCUIT DICE

(71) Applicant: Intel Corporation, Santa Clara, CA (US)

(72) Inventor: Bassam Ziadeh, Gilbert, AZ (US)

(21) Appl. No.: 16/438,916

(22) Filed: Jun. 12, 2019

(51) Int. Cl. H01L 21/673

(52) U.S. Cl. CPC H01L 21/67333; H01L 21/6732

(57) ABSTRACT

A transport carrier assembly for transporting integrated circuit dice may be formed comprising a rigid carrier frame and a compliant carrier insert attached within the rigid carrier frame. In one embodiment, the rigid carrier frame may conform to a standard, such that processing equipment may uniformly handle and transport the transport carrier assembly, and the compliant carrier insert may have differing configurations to house corresponding integrated circuit die configurations. In a further embodiment, the rigid carrier frame may comprise a substantially non-resilient material to provide structural integrity and the compliant carrier insert may comprise a substantially resilient material to protect the integrated circuit dice disposed therein during shipping and processing events.

### TECHNICAL FIELD

Embodiments of the present description generally relate to the field of integrated circuit device fabrication, and, more specifically, to trays that can be utilized to transport integrated circuit dice.

### BACKGROUND

The integrated circuit industry is continually striving to produce ever faster, smaller, and thinner integrated circuit packages and/or devices for use in various electronic products, including, but not limited to, computer servers and portable products, such as portable computers, electronic tablets, cellular phones, digital cameras, and the like.

As a part of this effort, some integrated circuit dice have become larger as more passive and active integrated circuitry is formed on a single piece of semiconductor material, such as silicon, germanium, silicon-germanium or a III-V compound semiconductor material, particularly with the adoption of reticle die stitching, as will be understood to those skilled in the art.

There are currently two primary ways to transport integrated circuit dice prior to their incorporation into integrated circuit packages. These methods are Die-On-Mylar (“DOM”) and Bare Die Tape (“BDT”). The Die-On-Mylar transport method, wherein an integrated circuit die is attached to a mylar film, is generally used for shipping integrated circuit dice to external vendors, as it can be safely packaged for transport. It is generally not used for internal processing transport, as it may present challenges with regard to damage to edges of the integrated circuit dice during transport caused by the integrated circuit dice colliding while on the mylar and may present challenges with the risk of remnant die, as will be understood to those skilled in the art. Additionally Die-On-Mylar requires specialize equipment (or the retrofitting of current equipment with die ejectors) for handling of the same.

The second method, i.e. Bare Die on Tape, comprises the utilization of a carrier tape having recesses for receiving each of the integrated circuit dice and a film disposed over the carrier tape for holding the integrated circuit dice in place. Once the carrier tape is loaded with the integrated circuit dice and sealed with the film, the tape is wound on a reel for transportation. However, current carrier tapes have a maximum width of about 44 millimeters. Thus, there is no solution for large integrated circuit dice, as they are moving toward widths of between about 60 and 70 millimeters. Furthermore, carrier tapes will not accommodate larger silicon interposers or Chip-on-Wafer-on-Substrate (CoWoS) complexes, which require large base dice to host the various chiplets, as will be understood to those skilled in the art. Moreover, the reel diameter and its hub diameter must also increase with increasing integrated circuit die size. The hub diameter must increase to reduce the overall bend that an individual integrated circuit die experiences during a tape winding process onto the reel to prevent any risk of cracking the integrated circuit dice. In order to ensure a minimum quantity of integrated circuit die on a reel, the reel diameter must increase to offset the increase in hub diameter, which presents handling and transportation issues with regard to the reels.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is an oblique view of the rigid carrier frame and the compliant carrier insert that are combined to form the transport carrier assembly, according to one embodiment of the present description.

FIG. 2 is an oblique view of a rigid carrier frame and a compliant carrier insert prior to combining to form the transport carrier assembly of FIG. 1, according to an embodiment of the present description.

FIG. 3 is a side cross-sectional view of a transport carrier assembly wherein the rigid carrier frame and the compliant carrier insert are secured to one another with either an adhesive or a weld, according to one embodiment of the present description.

FIG. 4 is a side cross-sectional view of a transport carrier assembly wherein the rigid carrier frame and the compliant carrier insert are secured to one another with overmolding, according to an embodiment of the present description.

FIG. 5 is a side cross-sectional view of the transport carrier assembly having nesting retention features, according to one embodiment of the present description.

FIG. 6 is a side cross-sectional view of stacked transport carrier assemblies, according to another embodiment of the present description.

FIG. 7 is a flow chart of a process of transporting integrated circuit dice with transport carriers, according to an embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include a transport carrier assembly for transporting integrated circuit dice, wherein the transport carrier assembly comprises a rigid carrier frame and a separate compliant carrier insert attached within the rigid carrier frame. In one embodiment, the rigid carrier frame may conform to a standard, such that processing equipment may uniformly handle and transport the transport carrier assembly, and the compliant carrier insert may have differing configurations to house corresponding integrated circuit die configurations. In a further embodiment, the rigid carrier frame may comprise a substantially non-resilient material to provide structural integrity and the compliant carrier insert may comprise a substantially resilient material to protect the integrated circuit dice disposed therein during shipping and processing events.

For the purpose of the present description, the term “compliant” may be defined to mean a material or structure that is resilient, wherein the material may be subjected to a stretching (elongation) force and/or a twisting (rotational torsion) force, and return to its original shape when the force(s) are released. The term “rigid” may be defined to mean a material or structure that is substantially non-resilient, such that it can bear a force, load, and/or stress without deformation.

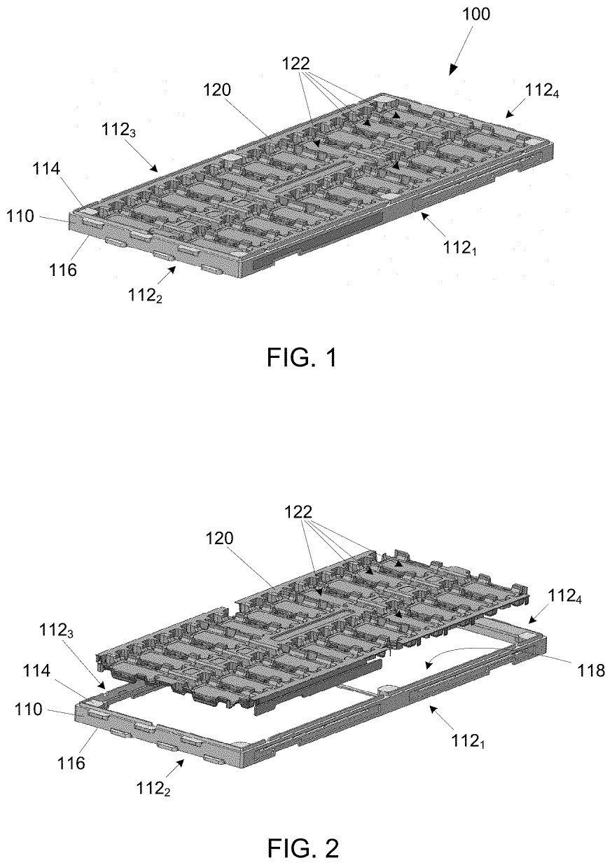

As shown in FIG. 1, a transport carrier assembly 100 may comprise a rigid carrier frame 110 and a compliant carrier insert 120 substantially housed within the rigid carrier frame 110. As shown in FIG. 2, the rigid carrier frame 110 may be a “picture frame” structure having four sides, e.g., a first side 112₁, a second side 112₂, a third side 112₃, and a fourth side 112₄ forming a substantially rectilinear shape and having at least one opening 118 extending form a first surface 114 of the rigid carrier frame 110 to an opposing second surface 116 of the rigid carrier frame 110. In one embodiment, the rigid carrier frame 110 may be made of a substantially non-resilient material to provide structural rigidity to the entire transport carrier assembly 100 (see FIG. 1), such that the compliant carrier insert 120 may be made of resilient materials to better protect integrated circuit dice (not shown) placed therein. The rigid carrier frame 110 may be formed by any appropriate process, including, but not limited to, injection molding, skiving, 3D printing, and the like. The rigid carrier frame 110 may be formed from any appropriate material, including metals and plastics (such as modified polyphenylene oxide (MPPO) and polyethersulfone (PES)). In one embodiment, the rigid carrier frame 110 may be formed to be compliant with the standards of the Joint Electron Digital Engineering Council (JEDEC), i.e. the council that sets industry standards. This would allow for the transport carrier assembly 100 to maintain compatibility with existing tools and load ports. As will be understood to those skilled in the art, the rigid carrier frame 110 may be formed to conform to the JEDEC thick tray profile standard or the JEDEC thin tray profile standard.

As further shown in FIGS. 1 and 2, the compliant carrier insert 120 may include at least one recess 122, wherein an integrated circuit die (not shown) may be secured within the at least one recess 122. The at least one recess 122 may be sized to accommodate any size of shape of integrated circuit die (not shown) and is not limited by tape width or the effects of winding about a hub, as previously discussed with regard to Bare Die on Tape transportation methods. The compliant carrier insert 120 may be formed by any appropriate process, including, but not limited to, injection molding, skiving, 3D printing, and the like. The rigid carrier frame 110 may be formed from any appropriate material, including, but not limited to, polystyrene and polycarbonate plastics. As will be understood to those skilled in the art, the use of polystyrene and polycarbonate plastics maintains an interface with the integrated circuit die that is similar to existing tapes used in the Bare Die Tape transportation method.

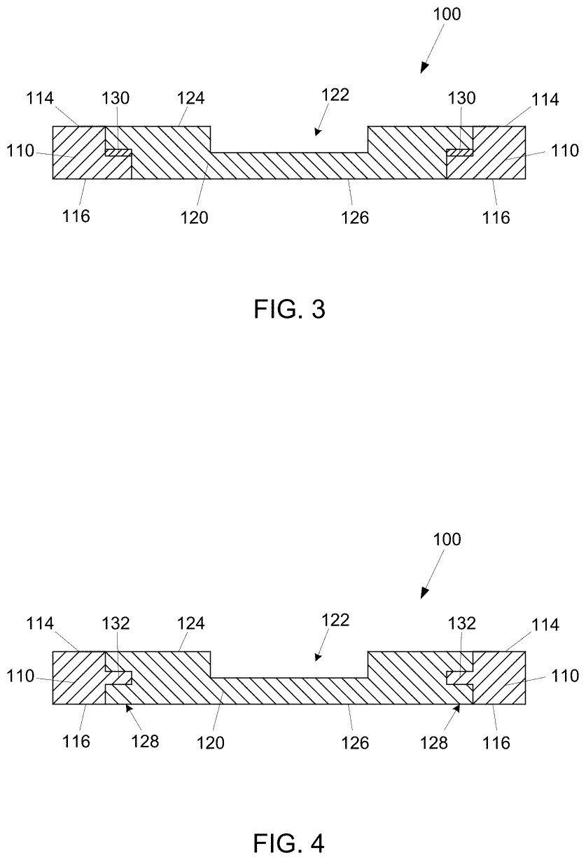

FIG. 3 illustrates a simplified cross-sectional view of the transport carrier assembly 100, wherein the compliant carrier insert 120 is fabricated separately from the rigid carrier frame 110, then inserted into the opening 118 (see FIG. 2) of the rigid carrier frame 110 and secured thereto. In one embodiment, as shown in FIG. 3, the compliant carrier insert 120 may secured to the rigid carrier frame 110 with an adhesive or ultrasonic welding (element 130 may represent the adhesive or a melted interface resulting from the ultrasonic weld).

FIG. 4 illustrates a simplified cross-sectional view of the transport carrier assembly 100, wherein the compliant carrier insert 120 is fabricated within the rigid carrier frame 110 with an overmolding process. With this process, the rigid carrier frame 110 is fabricated and the compliant carrier insert 120 is then molded over the rigid carrier frame 110, such that they interlock. In one embodiment, the rigid carrier frame 110 may have a flange 132 extending into the opening 118 (see FIG. 2) of the rigid carrier frame 110, wherein the flange 132 is captured by the compliant carrier insert 120 during the overmolding process to secure the compliant carrier insert 120 to the rigid carrier frame 110 with an overmolded portion 128 of the compliant carrier insert 120. The overmolding process may lessen or substantially eliminate undesired effects of welding and adhesives that could cause the transport carrier assembly 100 to warp.

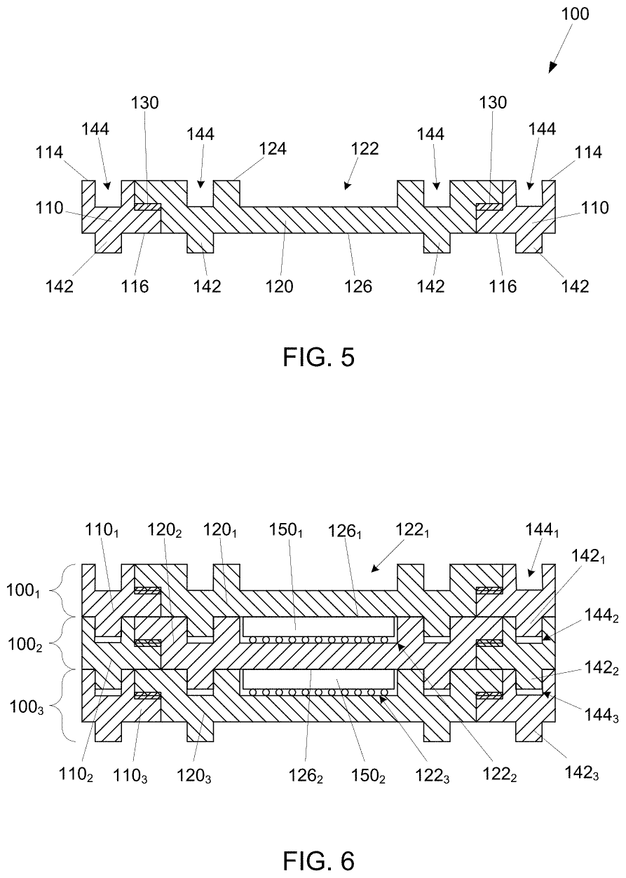

As previously discussed, integrated circuit dice (not shown) will be placed in the recesses 122 of the compliant carrier insert 120 for transportation. To ensure that the integrated circuit dice (not shown) do not move during transportation, nesting retention features may be designed into the rigid carrier frame 110 and/or the compliant carrier insert 120. As shown in FIG. 5, the transport carrier assembly 100 may include at least one projection 142 extending from the second surface 116 of the rigid carrier frame 110 and/or from a second surface 126 of the compliant carrier insert 120. The transport carrier assembly 100 may further include at least one socket 144 extending into the rigid carrier frame 110 from the first surface 114 thereof and/or extending into the compliant carrier insert 120 from a first surface 124 thereof. As shown in FIG. 6, transport carrier assemblies (shown as a first transport carrier assembly 1001, a second transport carrier assembly 100₂, and a third transport carrier assembly 100₃). As shown, the first transport carrier assembly 100₁ may be stacked on the second transport carrier assembly 100₂, such that projections 142₁ of the first transport carrier assembly 100₁ are inserted into sockets 144₂ of the second transport carrier assembly 100₂, thereby containing a first integrated circuit die 150₁ between the recess 122₂ in the compliant carrier insert 120₂ of the second transport carrier assembly 100₂ and the second surface 126₁ of the compliant carrier insert 120₁ of the first transport carrier 100₁. Furthermore, the second transport carrier assembly 100₂ may be stacked on the third transport carrier assembly 100₃, such that projections 142₂ of the second transport carrier assembly 100₂ are inserted into sockets 144₃ of the third transport carrier assembly 100₃, thereby containing a second integrated circuit die 150₂ between the recess 122₃ in the compliant carrier insert 120₃ of the third transport carrier assembly 100₃ and the second surface 126₂ of the compliant carrier insert 120₂ of the second transport carrier 100₂. The recess 122₁ in the compliant carrier insert 120₁ of the first transport carrier assembly 100₁, the sockets 144₁ of the first transport carrier assembly 100₁, the rigid carrier frame 110₁ of the first transport carrier assembly 100₁, the rigid carrier frame 110₂ of the second transport carrier assembly 100₂, the rigid carrier frame 110₃ of the third transport carrier assembly 100₃, and the projections 142₃ of the third transport carrier assembly 100₃ are labeled for clarity. With such a stacked configuration as shown in FIG. 6, no cover tape, such as would be necessary with a Bare Die Tape transportation process, is necessary. The elimination of a cover tape will ensure that the integrated circuit dice 150₁, 150₂ will not stick to remnant cover tape adhesive or get lodged between the cover tape and the carrier tape, as will be understood to those skilled in the art.

The embodiments of the present description have the benefit of a size that conforms to industry standards for transport and processing of the integrated circuit dice. This ensures that, regardless of size of the integrated circuit dice, only a single feeder system is required for a number of inspection and chip attach processes. The tray-based transport systems of the embodiments of the present description also have the benefit of being able to selectively pick integrated circuit dice from the transport carrier assembly without risking remnant die and has the benefit of allowing more favorable inspection, as it eliminates the optical issues associated with the cover tape of Bare Die Tape transportation systems.

Although the detailed description and the figures illustrate specific examples, the embodiment are not so limited. As will be understood to those skilled in the art, the embodiments may have a variety of configurations without departing from the spirit of the present description.

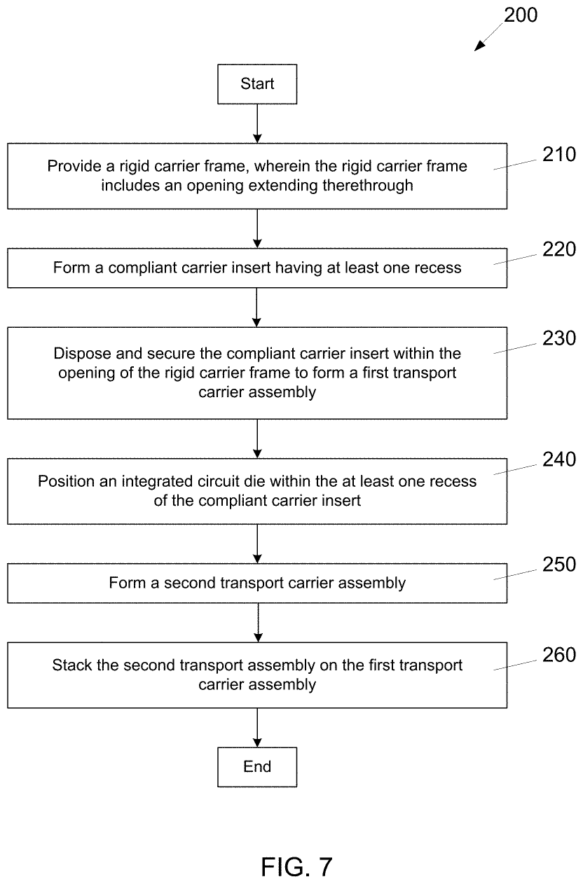

FIG. 7 is a flow chart of a process 200 of forming and loading a transport carrier assembly according to an embodiment of the present description. As set forth in block 210, a rigid carrier frame may be formed, wherein the rigid carrier frame includes an opening extending therethrough. A compliant carrier insert may be formed having at least one recess, as set forth in block 220. As set forth in block 230, the compliant carrier insert may be disposed within the opening and secured to the rigid carrier frame to form a first transport carrier assembly. An integrated circuit die may be position within the at least one recess of the compliant carrier insert, as set forth in block 240. As set forth in block 250, a second transport carrier assembly may be formed. The second transport carrier assembly may be stacked on the first transport carrier assembly, as set forth in block 260.

It is understood that the subject matter of the present description is not necessarily limited to specific applications illustrated in FIGS. 1-7. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is a transport carrier assembly comprising a rigid carrier frame, wherein the rigid carrier frame includes an opening extending therethrough; and a compliant carrier insert having at least one recess, wherein the compliant carrier insert is disposed within the opening and secured to the rigid carrier frame.

In Example 2, the subject matter of Example 1 can optionally include the compliant carrier insert being secured to the rigid carrier frame with an adhesive.

In Example 3, the subject matter of Example 1 can optionally include the compliant carrier insert being secured to the rigid carrier frame with a weld.

In Example 4, the subject matter of Example 1 can optionally include the compliant carrier insert being secured to the rigid carrier frame with an overmolded portion of the compliant carrier insert.

In Example 5, the subject matter of any of Examples 1 to 4 can optionally include the rigid carrier frame comprising modified polyphenylene oxide.

In Example 6, the subject matter of any of Examples 1 to 4 can optionally include the rigid carrier frame comprising polyethersulfone.

In Example 7, the subject matter of any of Examples 1 to 4 can optionally include the compliant carrier insert comprising polystyrene.

In Example 8, the subject matter of any of Examples 1 to 4 can optionally include the compliant carrier insert comprising polycarbonate.

In Example 9, the subject matter of any of Examples 1 to 8 can optionally include nesting retention features.

In Example 10, the subject matter of Example 9 can optionally include the nesting retention features including at least one projection extending from a second surface of the rigid carrier frame and/or from a second surface of the compliant carrier insert, and at least one socket extending into the rigid carrier frame from the first surface thereof and/or extending into the compliant carrier insert from a first surface thereof.

Example 11 is a method of fabricating a transport carrier assembly comprising forming a rigid carrier frame, wherein the rigid carrier frame includes an opening extending therethrough, forming a compliant carrier insert having at least one recess, disposing the compliant carrier insert within the opening, and securing the compliant carrier insert to the rigid carrier frame.

In Example 12, the subject matter of Example 11 can optionally include securing the compliant carrier insert to the rigid carrier frame with an adhesive.

In Example 13, the subject matter of Example 11 can optionally include securing the compliant carrier insert to the rigid carrier frame by ultrasonic welding the compliant carrier insert to the rigid carrier frame.

In Example 14, the subject matter of Example 11 can optionally include forming the compliant carrier insert, disposing the compliant carrier insert within the opening, and securing the compliant carrier insert to the rigid carrier frame comprises molding the compliant carrier insert within the opening and overmolding a portion of the compliant carrier insert to secure the compliant carrier insert to the rigid carrier frame.

In Example 15, the subject matter of any of Examples 11 to 14 can optionally include forming the rigid carrier frame from modified polyphenylene oxide.

In Example 16, the subject matter of any of Examples 11 to 14 can optionally include forming the rigid carrier frame from polyethersulfone.

In Example 17, the subject matter of any of Examples 11 to 14 can optionally include forming the compliant carrier insert from polystyrene.

In Example 18, the subject matter of any of Examples 11 to 14 can optionally include forming the compliant carrier insert from polycarbonate.

In Example 19, the subject matter of any of Examples 11 to 18 can optionally include forming nesting retention features.

In Example 20, the subject matter of Example 19 can optionally include forming the nesting retention features including forming at least one projection extending from a second surface of the rigid carrier frame and/or from a second surface of the compliant carrier insert, and forming at least one socket extending into the rigid carrier frame from the first surface thereof and/or extending into the compliant carrier insert from a first surface thereof.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A transport carrier assembly, comprising:
a rigid carrier frame, wherein the rigid carrier frame includes an opening extending therethrough; and
a compliant carrier insert having at least one recess, wherein the compliant carrier insert is disposed within the opening and secured to the rigid carrier frame.

2. The transport carrier assembly of claim 1, wherein the compliant carrier insert is secured to the rigid carrier frame with an adhesive.

3. The transport carrier assembly of claim 1, wherein the compliant carrier insert is secured to the rigid carrier frame with a weld.

4. The transport carrier assembly of claim 1, wherein the compliant carrier insert is secured to the rigid carrier frame with an overmolded portion of the compliant carrier insert.

5. The transport carrier assembly of claim 1, wherein the rigid carrier frame comprises modified polyphenylene oxide.

6. The transport carrier assembly of claim 1, wherein the rigid carrier frame comprises polyethersulfone.

7. The transport carrier assembly of claim 1, wherein the compliant carrier insert comprises polystyrene.

8. The transport carrier assembly of claim 1, wherein the compliant carrier insert comprises polycarbonate.

9. The transport carrier assembly of claim 1, further comprising nesting retention features.

10. The transport carrier assembly of claim 9, wherein the nesting retention features include at least one projection extending from a second surface of the rigid carrier frame and/or from a second surface of the compliant carrier insert, and at least one socket extending into the rigid carrier frame from the first surface thereof and/or extending into the compliant carrier insert from a first surface thereof.

11. A method of forming a transport carrier assembly, comprising:
forming a rigid carrier frame, wherein the rigid carrier frame includes an opening extending therethrough;
forming a compliant carrier insert having at least one recess;
disposing the compliant carrier insert within the opening; and
securing the compliant carrier insert to the rigid carrier frame.

12. The transport carrier assembly of claim 11, wherein securing the compliant carrier insert to the rigid carrier frame comprises securing the compliant carrier insert to the rigid carrier frame with an adhesive.

13. The transport carrier assembly of claim 11, wherein securing the compliant carrier insert to the rigid carrier frame comprises ultrasonic welding the compliant carrier insert to the rigid carrier frame.

14. The transport carrier assembly of claim 11, wherein forming a compliant carrier insert, disposing the compliant carrier insert within the opening, and securing the compliant carrier insert to the rigid carrier frame comprises molding the compliant carrier insert within the opening and overmolding a portion of the compliant carrier insert to secure the compliant carrier insert to the rigid carrier frame.

15. The transport carrier assembly of claim 11, wherein forming the rigid carrier frame comprises forming the rigid carrier frame from modified polyphenylene oxide.

16. The transport carrier assembly of claim 11, wherein forming the rigid carrier frame comprises forming the rigid carrier frame from polyethersulfone.

17. The transport carrier assembly of claim 11, wherein forming the compliant carrier insert comprises forming the compliant carrier insert from polystyrene.

18. The transport carrier assembly of claim 11, wherein forming the compliant carrier insert comprises forming the compliant carrier insert from polycarbonate.

19. The transport carrier assembly of claim 11, further comprising forming nesting retention features in the rigid carrier frame and/or the compliant carrier insert.

20. The transport carrier assembly of claim 19, wherein forming the nesting retention features include forming at least one projection extending from a second surface of the rigid carrier frame and/or from a second surface of the compliant carrier insert, and forming at least one socket extending into the rigid carrier frame from the first surface thereof and/or extending into the compliant carrier insert from a first surface thereof.
